(19) United States
(12) Patent Application Publication
(10) Pub. No.: US 2026/0324323 A1
(43) Pub. Date: Oct. 15, 2026

(54) METHOD OF FORMING SEMICONDUCTOR STRUCTURE, SEMICONDUCTOR STRUCTURE, AND SEMICONDUCTOR PROCESSING SYSTEM

(71) Applicant: ASM IP Holding B.V., Almere (NL)

(72) Inventors: JaeSoon Hwang, Anyang-si (KR); Seungju Chun, Hwaseong-si (KR); HaRim Kim, Hwaseong-si (KR); Yooncheol Shin, Hwaseong-si (KR); HieChul Kim, Hwaseong-si (KR); SungJoo Woo, Yongin-si (KR)

(21) Appl. No.: 19/638,328

(22) Filed: Apr. 3, 2026

Related U.S. Application Data
(60) Provisional application No. 63/785,169, filed on Apr. 8, 2025.

(51) Int. Cl. H10P 50/28; H01J 37/32; H10P 72/00

(52) U.S. Cl. CPC H10P 50/283; H01J 37/32449; H10P 72/0421; H01J 2237/334

(57) ABSTRACT

A method of forming a semiconductor structure is provided, including: in a process chamber, depositing a material on a sidewall of a recess. The method includes providing an etching gas into the process chamber. The method includes providing a diluting gas into the process chamber. The method includes providing a plasma into the process chamber.

### CROSS-REFERENCE TO RELATED APPLICATIONS

This application claims priority to U.S. Provisional Patent Application Ser. No. 63/785,169 filed Apr. 8, 2025 and titled METHOD OF FORMING SEMICONDUCTOR STRUCTURE, SEMICONDUCTOR STRUCTURE, AND SEMICONDUCTOR PROCESSING SYSTEM, the disclosure of which is hereby incorporated by reference in its entirety.

### BACKGROUND OF THE INVENTION

### Field of the Invention

The present disclosure relates to method of forming a semiconductor structure, and, in particular, it relates to method of forming a semiconductor structure that has recesses with uniformity across the substrate.

### Description of the Related Art

The next generation of semiconductor devices requires a more integrated pattern, and accordingly, as the feature sizes are reduced, more gap fill technology is required. There are various profile control methods in gap fill technology. General gap fill technologies include CVD and ALD processes, and additional inhibition and etching technologies are required for feature sizes that are difficult to achieve.

Among these technologies, etching encompasses physical etching methods and chemical etching technologies. In chemical etching, an etching method using an etching gas is mainly used, but there is a limitation on how much improvement can be achieved through etching. The desired profile will not be obtained if too much etching gas is applied, because the etching gas will etch even down to the deep area of the pattern. Likewise, the application of too little etching gas may obtain an improved profile, but it can deteriorate the etch uniformity in the wafer. The present disclosure includes an etch pattern profile and a method of improving uniform etch uniformity in a wafer by applying diluting gas to the existing etching gas.

Therefore, a method of forming a semiconductor structure that has recesses with uniformity across the substrate is desired.

### BRIEF SUMMARY OF THE INVENTION

An embodiment of the present disclosure provides a method of forming a semiconductor structure, including: in a process chamber, depositing a material on a sidewall of a recess. The method includes providing an etching gas into the process chamber. The method includes providing a diluting gas into the process chamber. The method includes providing a plasma into the process chamber.

In some embodiments, the etching gas includes fluorine. In some embodiments, the etching gas includes at least one of the following: NF₃, SF₆, F₂, ClF₃, and CF₄. In some embodiments, the etching gas is NF₃. In some embodiments, the diluting gas includes nitrogen. In some embodiments, the diluting gas includes at least one of the following: N₂, NH₃, N₂H₄, and N₂O. In some embodiments, the diluting gas is N₂.

In some embodiments, the flow of the etching gas and the flow of the diluting gas are at least overlapped. In some embodiments, the flow of the etching gas, the flow of the diluting gas, and the plasma are at least overlapped. In some embodiments, the duration of the step of providing the etching gas into the process chamber is longer than the duration of the step of providing the plasma into the process chamber. In some embodiments, the duration of the step of providing the diluting gas into the process chamber is longer than the duration of the step of providing the plasma into the process chamber. In some embodiments, the flow rate of the diluting gas is greater than or equal to 5,000 SCCM. In some embodiments, the flow rate of the diluting gas is greater than or equal to 7,000 SCCM. In some embodiments, the method further including repeating the step of depositing the material, the step of providing the etching gas, the step of providing the diluting gas, and the step of providing the plasma.

In some embodiments, the recess has an aspect ratio that is greater than or equal to 5:1. In some embodiments, the method further including providing an inert gas into the process chamber. In some embodiments, the recess is formed on a substrate.

An embodiment of the present disclosure provides a semiconductor structure formed on a substrate using the method.

In some embodiments, the side conformality of the remaining material is uniform across the substrate.

An embodiment of the present disclosure provides a semiconductor processing system, includes a process chamber, a susceptor, an etching gas source, a diluting gas source, a plasma source, and a controller. The susceptor is disposed in the process chamber and supporting a substrate. The etching gas source is configured and arranged to provide an etching gas into the process chamber. The diluting gas source is configured and arranged to provide a diluting gas into the process chamber. The plasma source is configured and arranged to provide a plasma into the process chamber. The controller is configured to control the flow of the diluting gas into the process chamber, so as to perform the method.

### BRIEF DESCRIPTION OF THE DRAWINGS

The present disclosure can be more fully understood by reading the subsequent detailed description and examples with references made to the accompanying drawings, wherein:

FIG. 1 is a schematic view of a portion of a semiconductor structure;

FIG. 2 is a schematic view of a method of forming a semiconductor structure according to some embodiments of the present disclosure;

FIG. 3 is a schematic view of a timing sequence according to some embodiments of the present disclosure;

FIG. 4A is a schematic view of the profile of a recess of a semiconductor structure at the center of a substrate;

FIG. 4B is a schematic view of the profile of a recess of a semiconductor structure at the edge of a substrate;

FIG. 4C is a schematic view of the profile of a recess of a semiconductor structure at the center of a substrate;

FIG. 4D is a schematic view of the profile of a recess of a semiconductor structure at the edge of a substrate;

FIG. 5 is a schematic view of a semiconductor structure 500 according to some embodiments of the present disclosure; and

FIG. 6 shows a semiconductor processing system illustrated in accordance with exemplary embodiments of the disclosure.

### DETAILED DESCRIPTION OF THE INVENTION

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide. In some embodiments, the substrate can have an OH termination. The OH termination can occur natively, e.g., it can occur through atmospheric oxidation, or the OH termination can be provided intentionally, e.g., by subjecting the substrate to a plasma treatment.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The particular implementations shown and described are illustrative of the disclosure and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

Exposure of a substrate to precursor can result in one or more of physisorption and chemisorption of at least one of precursor and precursor fragments on the substrate. Ones from the plurality of reactant pulses can result in one or more of physisorption and chemisorption of at least one of reactant and reactant fragments on the substrate.

It will be understood that although the terms “first,” “second,” and the like may be used herein to describe various members, regions, layers, and/or portions, these members, regions, layers, and/or portions should not be limited by these terms. The terms do not refer to a specific order, a vertical relationship, or a preference, and are only used to distinguish one member, region, or portion from another member, region, or portion. Accordingly, a first member, region, or portion that will be described below may refer to a second member, region, or portion without departing from the teaching of the present disclosure.

As used herein substantially or about the same means ±5%, ±2%, ±1%, or ±0.5% of another value or shape—e.g., one or more cross-sectional dimensions of the shape. The percentages can be absolute or relative.

In the drawings, variations from the shapes of the illustrations as a result, for example, of manufacturing techniques and/or tolerances, are to be expected. Thus, embodiments should not be construed as limited to the particular shapes of regions illustrated herein but may be to include deviations in shapes that result, for example, from manufacturing. Further, the drawing figures may be used to illustrate various features, which may not be drawn to scale.

Expressions, such as “at least one of,” when preceding a list of elements, modify the entire list of elements and do not modify the individual elements of the list.

As used herein, “atomic layer deposition,” abbreviated as “ALD,” refers to a method of depositing a film on a substrate by sequentially exposing its surface to alternate gas-phase reactants. In contrast to chemical vapor deposition, the different reactants are not simultaneously present in the reactor, but rather they are introduced as a series of sequential, non-overlapping pulses. In each of these pulses, the reactant reacts with the surface in a self-limiting way or a substantially self-limiting way. Further, ALD, as used herein, may also be meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of reactants. Plasma enhanced atomic-layer deposition (PEALD) refers to an ALD process, in which a plasma is applied during one or more of the ALD steps or substeps.

As used herein, “chemical vapor deposition,” abbreviated as “CVD,” refers to a method of depositing a film on a substrate by exposing its surface to one or more gaseous reactants, which react and/or decompose on the substrate surface to produce a desired film. Typically, CVD is performed by co-introducing the reactants into a reactor. Plasma enhanced chemical vapor deposition (PECVD) refers to a CVD process, in which a plasma is applied during one or more of the CVD steps or substeps.

As used herein, “chemisorption” refers to an adsorption process, caused by a reaction on an exposed surface, which creates, for example, a covalent or ionic bond between the surface and the adsorbate.

As used herein, a “film” refers to a continuous, substantially continuous, or non-continuous material that extends in a direction perpendicular to a thickness direction to cover at least a portion of a surface. A film can include two-dimensional materials, three-dimensional materials, nanoparticles or even partial or full molecular layers or partial or full atomic layers or clusters of atoms and/or molecules. A film may be built up from one or more non-discernable layers (e.g., monolayers or sub-monolayers) to produce a uniform or a substantially uniform material, wherein the number of layers influences the thickness of the material.

As used herein, the terms “layer,” “film,” and/or “thin film” can refer to any continuous or non-continuous structures and material deposited by the methods disclosed herein. For example, “layer,” “film,” and/or “thin film” could include 2D materials, nanorods, nanotubes, or nanoparticles or even partial or full molecular layers or partial or full atomic layers or clusters of atoms and/or molecules. “Layer,” “film,” and/or “thin film” can comprise material or a layer with pinholes, but still be at least partially continuous.

As used herein, a “gas” refers to a state of mater consisting of atoms or molecules that have neither a defined volume nor shape. A gas includes vaporized solid and/or liquid and may be constituted by a single gas or a mixture of gases, depending on the context.

As used herein, a “plasma” refers to an ionized gas comprising roughly equal numbers of negatively and positively charged species, generally electrons and ions. Excited and reactive species are also contained within the plasma, such as, for example, atoms and radicals, metastable atoms and molecules, and photons. A plasma discharge requires an externally imposed electric or magnetic field to ionize a gas. Plasma generation schemes and geometries, include, but are not limited to, capacitively coupled plasmas (CCPs), inductively coupled plasmas (ICPs), and RF-hollow cathode (HC) plasmas, which differ in their production of excited and reactive species and, as a result, they can provide very different fluxes of the various species.

As used herein, a “precursor” refers to a compound that participates in a chemical reaction to form another compound or element, wherein a portion of the precursor (an element or group within the precursor) is incorporated into the compound or element that results from the chemical reaction. The compound or element that results from the chemical reaction may be a layer and/or a film that is formed on a surface of a substrate.

As used herein, a “reactant” refers to a compound that participates in a chemical reaction to form another compound or element. In some instances, a reactant is a precursor. In other instances, the compound or element that results from the chemical reaction does not contain a portion of the reactant (an element or group within the reactant) and therefore the reactant is not a precursor.

As used herein, “self-limiting” refers to a process that proceeds by a finite course and that terminates once the finite course is complete. For example, a self-limiting surface reaction terminates when the surface becomes saturated and all of the available and/or accessible surface reactive sites are depleted. At maximum one monolayer may be formed on the surface.

As used herein, a “substituent” refers to an atom or a group of atoms that replaces one or more atoms (such as a hydrogen atom) or groups of atoms in a parent compound, thereby resulting in a new compound. The substituent is substituted for the original atom or a group of atoms in the parent molecule. For simplicity, a substituent may be indicated in a chemical formula as an “R” group and each “R” group in a compound may be independently selected unless otherwise specifically indicated that this is not the case. Examples of substituent groups include, but are not limited to: a hydrogen atom (H); an “alkyl group”, such as a saturated linear or branched C¬1 to C10 hydrocarbons, preferably C¬1 to C6 hydrocarbons (e.g., methyl, ethyl, propyl, iso-propyl, butyl, i-butyl, s-butyl, t-butyl, pentyl, 3-pentyl, neo-pentyl, and hexyl); a “cycloalkyl group”, such as C3 to C6 cyclic hydrocarbons (e.g., cyclopropyl, cyclobutyl, cyclopentyl, and cyclohexyl); an “alkenyl group”, such as C2 to C6-linear or branched unsaturated hydrocarbons (e.g., vinyl, allyl, propenyl, butenyl, pentenyl, hexenyl, butadienyl, pentadienyl, hexadienyl, ethynyl, propargyl, butynyl, pentynyl, and hexynyl); an “aryl group”, such as a phenyl, benzyl, tolyl, xylyl, naphthyl, cyclopentadienyl, and methyl, dimethyl, or ethyl cyclopentadienyl groups; a hydroxy group (OH); an “alkoxy group”, such as a linear or branched C1 to C10 alkoxy group, typically a C1 to C4 alkoxy group (e.g., methoxy, ethoxy, n-propoxy, i-propoxy, butoxy, iso-butoxy, sec-butoxy, and tert-butoxy); a hydroxyalkyl group such as a linear or branched a C1 to C10 hydroxyalkyl, typically a linear or branched C1 to C4 hydroxyalkyl (e.g., hydroxymethyl, hydroxyethyl, hydroxypropyl, hydroxybutyl, hydroxypentyl, and hydroxyhexyl); an “alkoxycarbonyl group”, such as a linear or branched C¬1 to C6 carbonyl hydrocarbon (e.g., methoxycarbonyl, ethoxycarbonyl, propoxycarbonyl, isopropoxycarbonyl, butoxycarbonyl, pentoxycarbonyl, and hexyloxycarbonyl); a thiol group (SH); an “alkylthiol group”, such as a linear or branched C¬1 to C6 thiols (e.g., thiolmethyl, thiolethyl, thiolpropyl, thiolbutyl, thiolpentyl, and thiolhexyl); a halide (X), such as fluoride (F), chloride (C1), bromide (Br), and iodide (I); and an “haloalkyl group”, such as a linear or branched C¬1 to C6 alkylhalides having one or more halogen atoms (e.g., iodomethyl, bromomethyl, chloromethyl, fluoromethyl, trifluoromethyl, 2-chloroethyl, 2-fluoroethyl, 2,2,2-trifluoroethyl, and pentafluoroethyl). A substituent group may, in and of itself, be substituted. For example, a hydroxyalkyl group is a substituted alkyl group, where a H atom on the alkyl group is replaced with an OH group.

Articles “a” or “an” refer to a species or a genus including multiple species, depending on the context. As such, the terms “a/an,” “one or more” and “at least one” can be used interchangeably herein. It is also to be noted that the terms “comprising,” “including,” and “having” can be used interchangeably.

The term “about” generally refers to a range of numbers that is considered equivalent to the recited value (e.g., having the same function or result). In some instances, the term about may include numbers that are rounded to the nearest significant figure.

The term “essentially” as applied to a composition, a method, or a system generally means that the additional components do not substantially modify the properties and/or function of the composition, the method, or the system.

The term “substantially” as applied to a composition, a method, or a system generally refers to a proportion of a value, a property, a characteristic, or the like, or conversely a lack thereof, that is at least about 70%, at least about 80%, at least about 90%, at least about 95%, at least about 97%, at least about 98%, at least about 99%, at least about 99.5%, at least about 99.9%, or more, or any proportion between about 70% and about 100%. In some embodiments, the term “substantially” means a proportion of about 90%, about 95%, about 97%, about 98%, about 99%, about 99.5%, or about 99.9%.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X1-Xn, Y1-Ym, and Z1-Zo, the phrase is intended to refer to a single element selected from X, Y, and Z, a combination of elements selected from the same class (e.g., X1 and X2) as well as a combination of elements selected from two or more classes (e.g., Y1 and Zo).

It should be understood that every numerical range given throughout this disclosure is deemed to include the upper and the lower end points, and each and every narrower numerical range that falls within such broader numerical range, as if such narrower numerical ranges were all expressly written herein. By way of example, the phrase “from about 2 to about 4” or “from 2 to 4” includes 2 and 4 and the whole number and/or integer ranges from about 2 to about 3, from about 3 to about 4 and each possible range based on real (e.g., irrational and/or rational) numbers, such as from about 2.1 to about 3.9, from about 2.1 to about 3.4, and so on.

The present disclosure generally relates to methods of forming an underlayer over a substrate using CVD (such as PECVD) or ALD (such as PEALD), a semiconductor structure with the underlayer and a reactor system for performing the method, and in particular to the use of a precursor gas with at least one carbon-carbon double bond to form an underlayer with carbon-carbon double bonds to offer dose reduction for EUV lithography. Various aspects of the methods and systems and the benefits derived therefrom will now be described.

The present disclosure allows uniform etching of high aspect ratio (HAR) features across the substrate. In some examples, each deposition cycle deposits a layer of material. After multiple deposition cycles are performed, an etching cycle is performed to etch back upper portions of the features.

A process including deposition, etch and deposition (DED) can be performed to increase the effectiveness of gapfill in the feature. In other words, the feature is partially filled by the material and then etching is performed. The etching removes some of the material that is closer to the top of the feature as compared to the bottom of the feature. As a result, the recess remains open longer and more of the material is deposited lower in the feature.

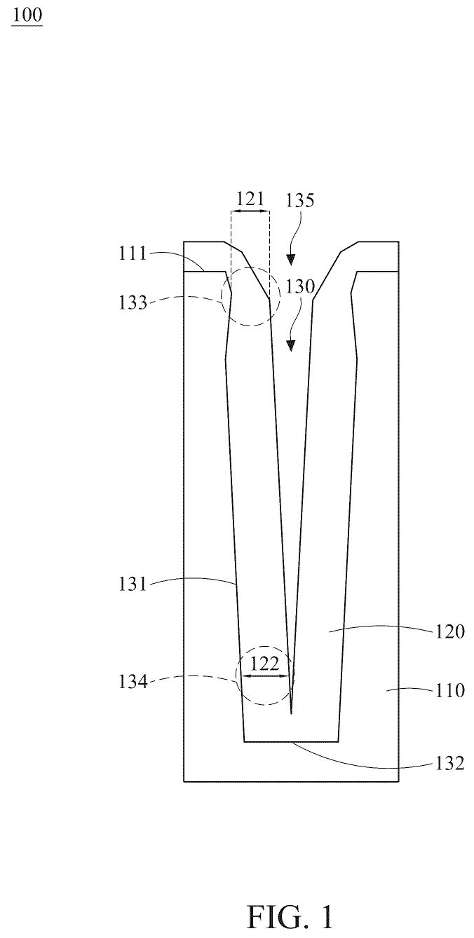

Please refer to FIG. 1, FIG. 1 is a schematic view of a portion of a semiconductor structure 100. The semiconductor structure 100 includes a substrate 110 and a material 120. The material 120 overlays on the substrate 110. A recess 130 is formed on the substrate 110. The recess 130 includes a sidewall 131 and a bottom 132. The material 120 overlays on the sidewall 131 and the bottom 132.

In some embodiments, the material 120 can be a dielectric layer. In some embodiments, the dielectric layer can comprise silicon or a metal. For example, the dielectric layer may comprise one or more of SiN, SiON, SiC, SiCN, SiCO, SiCOH, or SiCON. For example, the dielectric layer may comprise one or more of TIN, TiC, HAN, HfC, WC, WN, MOC, MON, AlN, AIC, ZrO or ZrC.

In some embodiments, the recess can comprise trenches having a width of between 10 nm and 100 nm. For example, the recess may comprise trenches having a width of 10 nm, 20 nm, 30 nm, 40 nm, 50 nm, 60 nm, 70 nm, 80 nm, 90 nm, 100 nm, 200 nm, 300 nm, 400 nm, 500 nm, 600 nm, 700 nm, 800 nm, 900 nm, 1000 nm, or more. The recess may comprise trenches having a width of less than 10 nm. The recess may also comprise trenches having a width of more than 100 nm. In some embodiments, the recess can have an aspect ratio of between 1 and 10. For example, the recess can have an aspect ratio of 1, 2, 3, 4, 5, 6, 7, 8, 9, or 10. In some embodiments, the recess has an aspect ratio that is greater than or equal to 5:1. In some embodiments, the width and the aspect ratio is dependent on the application area. For example, the width ranges from 5 nm to 100 nm and the aspect ratio from 2 to 100 corresponds to nanometer-level logic and memory devices, and the width ranges from 100 to 1000 nm and the aspect ratio from 1 to 100 corresponds to TSV (Through Silicon Via) for connecting nanometer-level devices in three dimensions.

Back to FIG. 1, the sidewall 131 is slanted relative to the bottom, and the width of the bottom 132 is less than the width of the opening 135 of the recess 130. Typically, a recess with wide opening and narrow bottom results in a “positive slope” recess. A positive slope recess can be filled easily without forming a void.

Back to FIG. 1, the upper portion 133 of the recess 130 is closer to the opening 135 of the recess 130 and the flat portion 111 of the substrate 110. The lower portion 134 of the recess 130 is closer to bottom 132 of the recess 130. The material 120 has a thickness 121 at the upper portion 133, and the material 120 has a thickness 122 at the lower portion 134. To maintain the recess with wide opening and narrow bottom, the thickness 122 at the lower portion 134 is desired to be greater than the thickness 121 at the upper portion 133. Moreover, the side conformality of the material 120 is defined as:

$$side conformality of material 120 = \frac{thickness 1 \; 22 at lower portion 134}{thickness 121 at upper portion 133} \times 100 \% .$$

Since the thickness 122 at the lower portion 134 is greater than the thickness 121 at the upper portion 133, the side conformality of the material 120 is greater than 100% (side conformality of material 120>100%).

Ideally, the side conformality of material 120 is high enough to achieve a void-free gapfill in the recess. In some embodiments, the side conformality of material 120 across the substrate 110 is greater than 105%. In some embodiments, the side conformality of material 120 across the substrate 110 is near 110%.

Ideally, the side conformality of material 120 across the substrate 110 is maintain substantially consistent, and the variation of side conformality across the substrate 110 is ideally to be small, so as to obtain a uniform substrate. That is, the side conformality of material 120 near the central axis of the substrate 110 is ideally to be close to the side conformality of material 120 near the edge of the substrate 110.

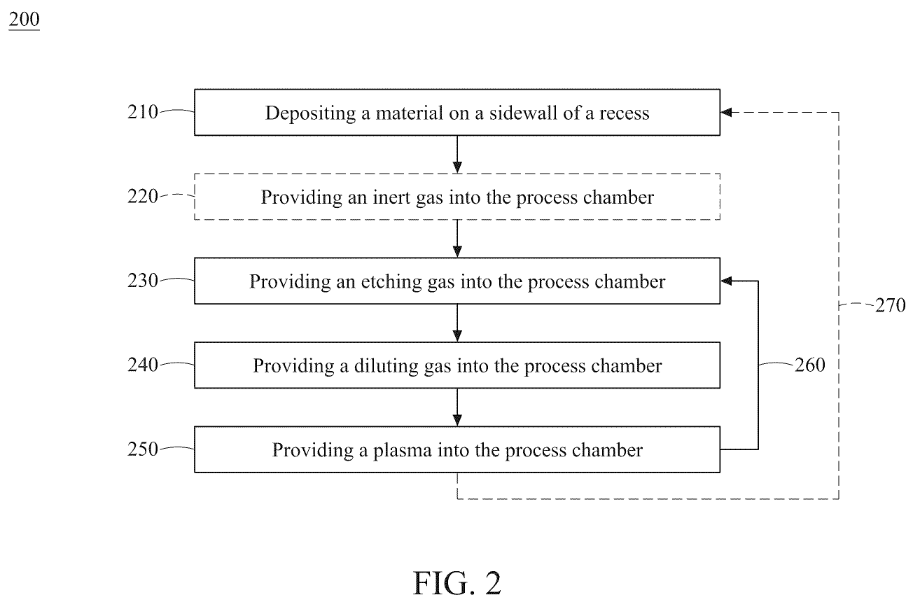

Please refer to FIG. 2, FIG. 2 is a schematic view of a method 200 of forming a semiconductor structure according to some embodiments of the present disclosure.

In step 210, depositing a material on a sidewall of a recess. Step 210 is performed in a process chamber with a substrate including the recess.

In some embodiments, the material can be a dielectric layer. In some embodiments, the dielectric layer can comprise silicon or a metal. For example, the dielectric layer may comprise one or more of SiN, SiON, SiC, SiCN, SiCO, SiCOH, or SiCON. For example, the dielectric layer may comprise one or more of TiN, TiC, HAN, HfC, WC, WN, MOC, MON, AlN, AIC, ZrO or ZrC.

Next, step 220 involves providing an inert gas into a process chamber. The inert gas can be a noble gas. For example, the inert gas can be helium (He) or argon (Ar). Step 220 is optional. In some embodiments, step 220 is performed. In some embodiments, step 220 is omitted.

Next, step 230 involves providing an etching gas into the process chamber.

In some embodiments, the etching gas includes fluorine (F). In some embodiments, the etching gas includes at least one of the following: NF₃, SF₆, F₂, ClF₃, and CF₄. In some embodiments, the etching gas is NF₃.

In some embodiments, the flowrate of the etching gas is maintained at greater than about 0 SCCM, about 1 SCCM or greater, typically from about 1 SCCM to about 100,000 SCCM, more typically from about 1 SCCM to about 10,000 SCCM, more typically from about 1 SCCM to about 5,000 SCCM, more typically from about 1 SCCM to about 1,000 SCCM, more typically from about 1 SCCM to about 500 SCCM, more typically from about 1 SCCM to about 200 SCCM, more typically from about 1 SCCM to about 100 SCCM, more typically from about 1 SCCM to about 50 SCCM, more typically from about 1 SCCM to about 10 SCCM, or any intermediate range of flowrate between about 1 SCCM and about 100,000 SCCM. In some embodiments, the flowrate of the etching gas may be maintained at 1 SCCM or greater, at 10 SCCM or greater, at 50 SCCM or greater, at 100 SCCM or greater, at 200 SCCM or greater, at 500 SCCM or greater, at 1,000 SCCM or greater, at 5,000 SCCM or greater, or at 10,000 SCCM or greater. In some embodiments, the flowrate of the etching gas may be maintained at about 1 SCCM, at about 10 SCCM, at about 50 SCCM, at about 100 SCCM, at about 200 SCCM, at about 500 SCCM, at about 1,000 SCCM, at about 5,000 SCCM, at about 10,000 SCCM, or at about 100,000 SCCM.

In a specific embodiment, the flow rate of the diluting gas is greater than or equal to 5,000 SCCM. In a specific embodiment, the flow rate of the diluting gas is greater than or equal to 7,000 SCCM.

Next, step 240 involves providing a diluting gas into the process chamber. In some embodiments, the step 230 and the step 240 are performed at the same time. In some embodiments, the step 230 is performed prior to the step 240. In some embodiments, the step 240 is performed prior to the step 230.

The diluting gas helps the etching gas to spread across the substrate, and therefore the etching gas is uniform in the process chamber. For example, the concentration of the etching gas is substantially uniform over the substrate. That is, the concentration of the etching gas over the center of the substrate is substantially the same as the concentration of the etching gas over the edge of the substrate.

In some embodiments, the diluting gas comprises nitrogen (N). In some embodiments, the diluting gas comprises at least one of the following: N₂, NH₃, N₂H₄, and N₂O. In some embodiments, the diluting gas is N₂.

In some embodiments, the flowrate of the diluting gas is greater than the flowrate of the etching gas. In some embodiments, the flowrate of the diluting gas is less than the flowrate of the etching gas. In some embodiments, the flowrate of the diluting gas is the same as the flowrate of the etching gas.

In some embodiments, the flowrate of the diluting gas is maintained at greater than about 0 SCCM or greater, about 1 SCCM or greater, typically from about 1 SCCM to about 100,000 SCCM, more typically from about 1 SCCM to about 10,000 SCCM, more typically from about 1 SCCM to about 5, 000 SCCM, more typically from about 1 SCCM to about 1,000 SCCM, more typically from about 1 SCCM to about 500 SCCM, more typically from about 1 SCCM to about 200 SCCM, more typically from about 1 SCCM to about 100 SCCM, more typically from about 1 SCCM to about 50 SCCM, more typically from about 1 SCCM to about 10 SCCM, or any intermediate range of flowrate between about 1 SCCM and about 100,000 SCCM. In some embodiments, the flowrate of the diluting gas may be maintained at 1 SCCM or greater, at 10 SCCM or greater, at 50 SCCM or greater, at 100 SCCM or greater, at 200 SCCM or greater, at 500 SCCM or greater, at 1,000 SCCM or greater, at 5,000 SCCM or greater, or at 10,000 SCCM or greater. In some embodiments, the flowrate of the diluting gas may be maintained at about 1 SCCM, at about 10 SCCM, at about 50 SCCM, at about 100 SCCM, at about 200 SCCM, at about 500 SCCM, at about 1,000 SCCM, at about 5,000 SCCM, at about 10,000 SCCM, or at about 100,000 SCCM.

Next, step 250 involves providing a plasma into the process chamber.

The etching gas forms radicals under the plasma. In some embodiments, the etching gas forms F radicals (F*) under the plasma. With the help of diluting gas, F radicals are well spread over the substrate, and the concentration of the F radicals over the center of the substrate and the concentration of the F radicals over the edge of the substrate are uniform.

Moreover, with the existing of diluting gas, the etching gas forms NF₂. For example, in the embodiment that the etching gas is NF₃ and the diluting gas is N₂, the reduction formula is: NF₃+N₂→NF₂. This reduces the F radicals, and the positive slope recess can be formed.

Therefore, the substrate is uniform, and the recess are positive sloped profile.

In some embodiments, the RF power for generating the plasma is maintained at greater than about 0 W or greater, about 0.1 W or greater, typically from about 0.1 W to about 100,000 W, more typically from about 1 W to about 10,000 W, more typically from about 1 W to about 5, 000 W, more typically from about 1 W to about 1,000 W, more typically from about 1 W to about 500 W, more typically from about 1 W to about 200 W, more typically from about 1 W to about 100 W, more typically from about 1 W to about 50 W, more typically from about 1 W to about 10 W, or any intermediate range of flowrate between about 1 W and about 100,000 W. In some embodiments, the flowrate of the diluting gas may be maintained at 0.1 W or greater, at 1 W or greater, at 10 W or greater, at 50 W or greater, at 100 W or greater, at 200 W or greater, at 500 W or greater, at 1,000 W or greater, at 5,000 W or greater, or at 10,000 W or greater. In some embodiments, the flowrate of the diluting gas may be maintained at about 0.1 W, at about 1 W, at about 10 W, at about 50 W, at about 100 W, at about 200 W, at about 500 W, at about 1,000 W, at about 5,000 W, at about 10,000 W, or at about 100,000 W.

In some embodiments, the duration of the plasma is about 100 seconds or less, typically from about 0.01 seconds to about 100 seconds, more typically from about 0.01 seconds to about 50 seconds, more typically from about 0.01 seconds to about 10 seconds, more typically from about 0.01 s second to about 5 seconds, more typically from about 0.01 seconds to about 1 second, more typically from about 0.01 seconds to about 0.5 seconds, more typically from about 0.01 seconds to about 0.1 seconds, more typically from about 0.1 seconds to about 100 seconds, more typically from about 1 second to about 50 seconds, more typically from about 0.1 seconds to about 10 seconds, more typically from about 0.1 seconds to about 5 seconds, more typically from about 0.1 seconds to about 1 second, more typically from about 0.1 seconds to about 0.5 seconds, more typically from about 0.5 seconds to about 100 seconds, more typically from about 0.5 seconds to about 50 seconds, more typically from about 0.5 seconds to about 10 seconds, more typically from about 0.5 seconds to about 5 seconds, more typically from about 0.5 seconds to about 1 second, more typically from about 1 second to about 100 seconds, more typically from about 1 second to about 50 seconds, more typically from about 1 second to about 10 seconds, more typically from about 1 second to about 5 seconds, more typically from about 5 seconds to about 100 seconds, more typically from about 5 seconds to about 50 seconds, more typically from about 5 seconds to about 10 seconds, or any intermediate range of times between about 0.01 seconds and about 100 seconds. In some embodiments, the RF power may be maintained at about 100 seconds or less, about 50 seconds or less, about 10 seconds or less, about 5 seconds or less, about 1 second or less, about 0.5 seconds or less, about 0.1 seconds or less. In some embodiments, the RF power may be maintained at about 0.01 seconds, about 0.1 seconds, about 0.5 seconds, about 1 second, about 5 seconds, about 10 seconds, about 50 seconds, or about 100 seconds.

The method 200 also includes a sub-cycle 260. The sub-cycle 260 includes step 230, step 240, and step 250. The sub-cycle 260 is also called an etch cycle. In some embodiments, the sub-cycle 260 can be repeated for a plurality of times until a desired etching depth is reached.

According to some embodiments, etch cycles may be performed at temperatures ranging from about 20 to about 1200° C., about 50 to about 800° C., about 75 to about 600° C., about 300° C. to about 500° C., or from about 350° C. to about 450° C. In some embodiments, the temperature is greater than about 20, 50 or 100° C., but less than about 1000, 800, 600 or 500° C. In some embodiments, the cycles are carried out at a temperature of about 450° C.

The pressure in the process chamber for the etch cycles for some embodiments can be typically from about 10E−9 torr to about 760 torr, or about 0.001 to about 100 torr. However, in some cases, the pressure will be higher or lower than this range, as can be determined by the skilled artisan given the particular circumstances. In some embodiments, a pressure of less than 2 torr is utilized. In some cases the reactor can be operated either in isothermal (such as hot-wall) or non-isothermal (such as cold-wall) conditions. In some embodiments the reactor itself does not interact with etching chemistries and may also not interact with substrates. In some cases reactor can comprise a hot-wall, cold-wall or warm-wall type of process chamber.

In some embodiments, the etch cycle has an average etch rate of about 0.01 to about 5 Å/cycle. Etch rate is defined as amount of material or thickness of film is removed after each cycle. In some embodiments, the average etch rate is about 0.01 to 0.1 Å/cycle or from 0.1 to about 2 Å/cycle or in some cases even higher than 2 Å/cycle. In some embodiments, the average etch rate is more than about 0.1 Å/cycle, more than about 0.5 Å/cycle, more than about 1.0 Å/cycle, more than about 2.0 Å/cycle, more than about 3.0 Å/cycle, more than about 5.0 Å/cycle, more than about 10 Å/cycle or more than about 20 Å/cycle and in some instances if continuous flow is applied with flow rate modification or the exposure times are long enough the etch rates can be more than about 30 Å/cycle, more than about 50 Å/cycle or about 100 Å/cycle. The present pre-cleaning process is not limited by any particular form of cyclic etching. In some embodiments, the plasma etch cycle can have an etch rate of about “50 Å/cycle. In some embodiments, the modification relies on the ion implantation depth for the process. For H₂ this can be several nm. In some embodiments, the EPC can be increased by increasing the substrate bias. In some embodiments, etch rates of 100 Å/cycle can be obtained. In thermal etch cycle (e.g., ALE), the etch rate can be in the 0.1-3 Å/cycle range as this relies more heavily on surface reactions.

In some embodiments the etch selectivity i.e. the ratio of material (thickness, mass or amount of atoms/molecules) removed from the desired surface/material to material removed from the non-desired surface/materials or surfaces/materials, is from more than about 2:1, more than about 3:1, more than about 5:1, more than about 7:1, more than about 10:1, more than about 15:1, more than about 20:1, more than about 30:1, more than about 50:1, more than about 100:1, more than about 1000:1, more than about 10,000:1 or greater. In some embodiments no substantial amount of material is removed from the non-desired surface/material. In some embodiments, this ratio is cyclic etch process dependent.

The method 200 also includes an optional super-cycle 270. The super-cycle 270 includes step 210, step 220, step 230, step 240, and step 250. The super-cycle 270 includes deposition, etching, and deposition (DED), and thus the super-cycle 270 can be performed to increase the effectiveness of gapfill in the recess. The super-cycle 270 can also achieve a void-free gapfill in the recess. The super-cycle 270 can also achieve a void-free gapfill in the recess. In some embodiments, the super-cycle 270 can be repeated for a plurality of times until the recess is filled.

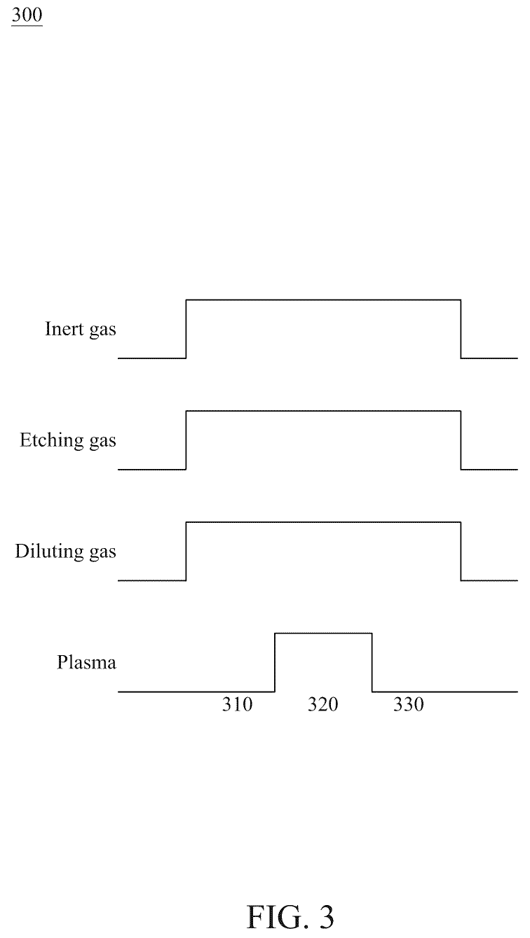

Please refer to FIG. 3, FIG. 3 is a schematic view of a timing sequence 300 according to some embodiments of the present disclosure.

The inert gas, the etching gas, and the diluting gas are provided at timing 310; that is the flow of the etching gas and the flow of the diluting gas are at least overlapped. In timing 310, the plasma is not ignited.

The plasma is pulsed at timing 320, and the inert gas, the etching gas, and the diluting gas are still provided; that is the flow of the etching gas, the flow of the diluting gas, and the plasma are at least overlapped.

The plasma is off at timing 330, and the inert gas, the etching gas, and the diluting gas are still provided; that is, the duration of the step of providing the etching gas into the process chamber is longer than the duration of the step of providing the plasma into the process chamber; and the duration of the step of providing the diluting gas into the process chamber is longer than the duration of the step of providing the plasma into the process chamber.

In some embodiments, timing 310, timing 320, and timing 330 can be repeated for a plurality of times until a desired etching depth is reached.

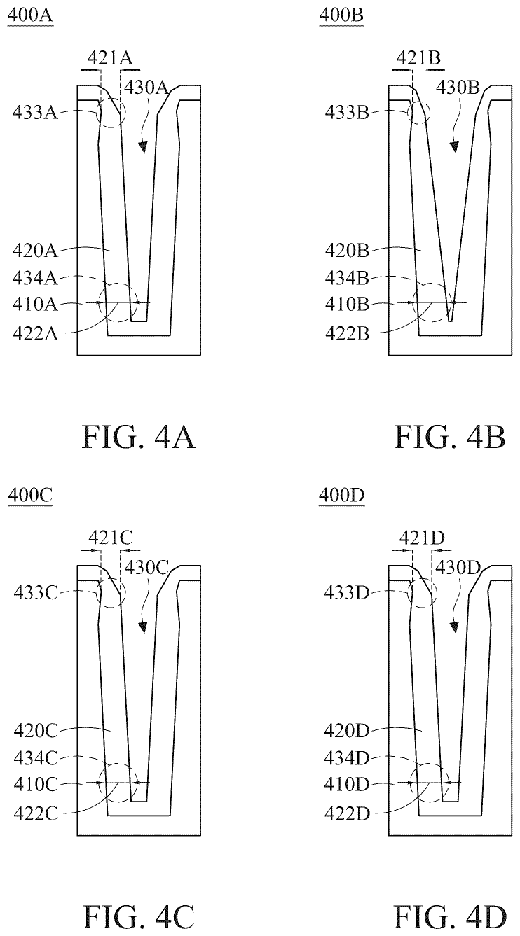

Please refer to FIG. 4A and FIG. 4B, FIG. 4A and FIG. 4B show the recesses etched under low flowrate of diluting gas; wherein FIG. 4A is a schematic view of the profile of a recess 430A of a semiconductor structure 400A at the center of a substrate 410A; and FIG. 4B is a schematic view of the profile of a recess 430B of a semiconductor structure 400B at the edge of a substrate 410B.

It can be seen that the thickness of the material 420A at the upper portion 433A is substantially thicker than the thickness of the material 420B at the upper portion 433B; the thickness of the material 420B at the lower portion 434B is substantially thicker than the thickness of the material 420A at the lower portion 434A. Thus, the side conformality of the material 420A ((thickness 422A at lower portion 434A)/(thickness 421A at upper portion 433A)) and the side conformality of the material 420B ((thickness 422B at lower portion 434B)/(thickness 421B at upper portion 433B)) is not uniform.

Please refer to FIG. 4C and FIG. 4D, FIG. 4C and FIG. 4D show the recesses etched under high flowrate of diluting gas; wherein FIG. 4C is a schematic view of the profile of a recess 430C of a semiconductor structure 400C at the center of a substrate 410C; and FIG. 4D is a schematic view of the profile of a recess 430D of a semiconductor structure 400D at the edge of a substrate 410D.

It can be seen that the thickness of the material 420C at the upper portion 433C is similar to the thickness of the material 420D at the upper portion 433D; the thickness of the material 420C at the lower portion 434C is similar to the thickness of the material 420D at the lower portion 434D. Thus, the side conformality of the material 420C ((thickness 422C at lower portion 434C)/(thickness 421C at upper portion 433C)) and the side conformality of the material 420D ((thickness 422D at lower portion 434D)/(thickness 421D at upper portion 433D)) is uniform.

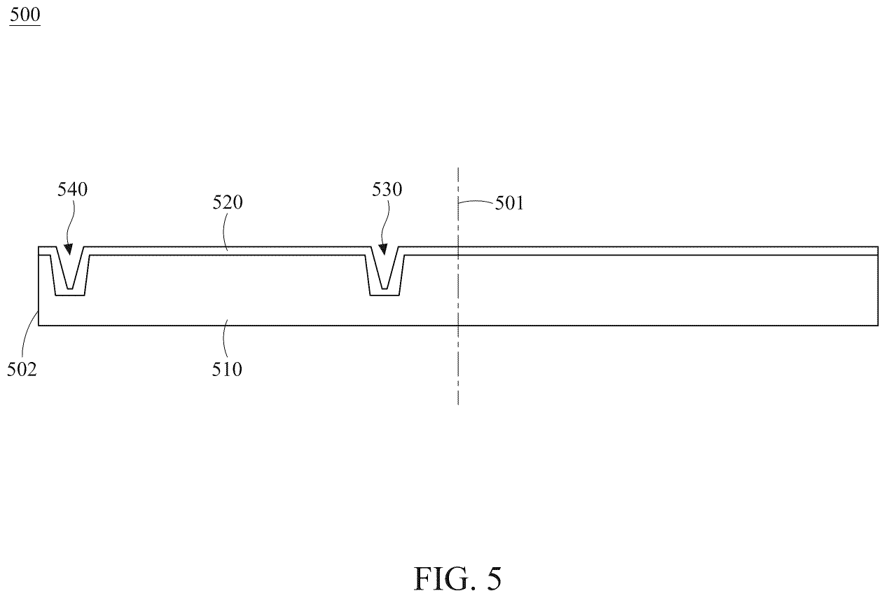

FIG. 5 is a schematic view of a semiconductor structure 500 according to some embodiments of the present disclosure.

The semiconductor structure 500 includes a substrate 510 and a material 520 overlays on the substrate 510. A recess 530A is formed on the substrate 510 and is located near the central axis 501 of the substrate 510. A recess 530B is formed on the substrate 510 and is located near the edge 502 of the substrate 510. The recess 530A and the recess 530B are positive sloped. The side conformality of the material 520 in the recess 530A is similar to the material 520 in the recess 530B; that is, the side conformalities are uniform across the substrate 510. Furthermore, the substrate 510 is uniform across the substrate as well.

In some embodiments, the semiconductor structure 500 is formed using the method 200. In some embodiments, the semiconductor structure 500 is formed using the timing sequence 300.

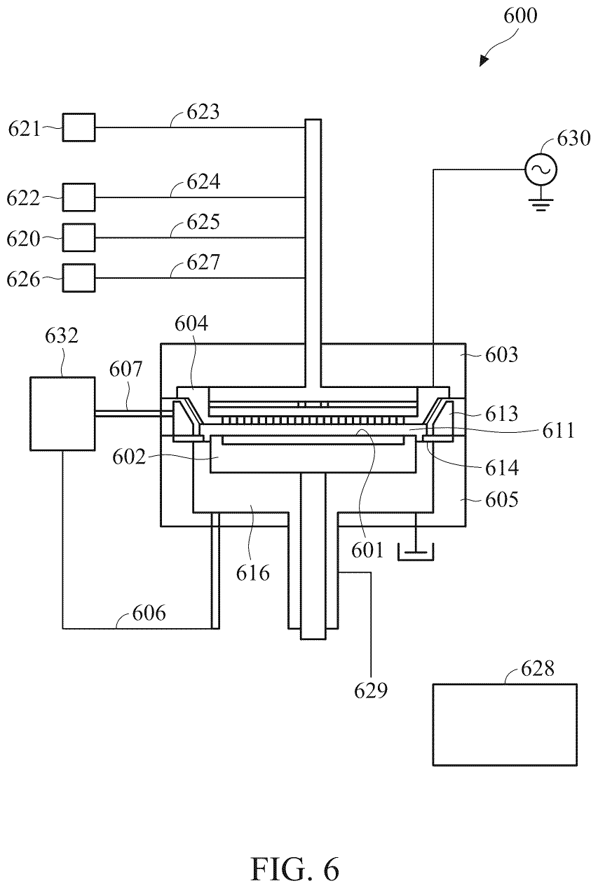

Turning now to FIG. 6, a semiconductor processing system 600 is illustrated in accordance with exemplary embodiments of the disclosure. Semiconductor processing system 600 can be used to perform one or more steps or substeps as described herein and/or to form one or more structures or portions thereof as described herein.

Semiconductor processing system 600 includes a pair of electrically conductive flat-plate electrodes 604, 602 in parallel and facing each other in the interior 611 (reaction zone) of a process chamber 603. Although illustrated with one process chamber, semiconductor processing system 600 can include two or more process chambers. A plasma can be excited within process chamber 603 by applying, for example, HRF power (e.g., 100 kHz, 13.56 MHz, 27 MHz, 2.45 GHZ, or any values therebetween) from plasma source 630 to one electrode (e.g., upper electrode 604) and electrically grounding the other electrode (e.g., lower electrode 602). A temperature regulator can be provided in a lower stage 602 (the lower electrode), and a temperature of a substrate 601 placed thereon can be kept at a desired temperature, such as the substrate temperatures noted above. Upper electrode 604 can serve as a gas distribution device, such as a shower plate or showerhead. Etching gas, diluting gas and/or inert gas, if any, or the like can be introduced into process chamber 603 using one or more of a first gas line 623, a second gas line 624, a third gas line 625, and a fourth gas line 627, from a first source 621, a second source 622, a third source 620, and a fourth source 626, respectively, and through the shower plate 604. Although illustrated with four gas lines, semiconductor processing system 600 can include any suitable number of gas lines. By way of examples, the first source 621 can correspond to an etching gas source, the second source 622 can correspond to a diluting gas source, the third source 620 can correspond to a purge gas source, and the fourth source 626 can correspond to an inert gas source.

In process chamber 603, a circular duct 613 with an exhaust line 607 can be provided, through which gas in the interior 611 of the process chamber 603 can be exhausted. Additionally, a transfer chamber 605, disposed below the process chamber 603, can be provided with a seal gas line 629 to introduce seal gas into the interior 611 of the process chamber 603 via the interior 616 (transfer zone) of the transfer chamber 605, wherein a separation plate 614 for separating the reaction zone and the transfer zone can be provided (a gate valve through which a substrate is transferred into or from the transfer chamber 605 is omitted from this figure). The transfer chamber can also be provided with an exhaust line 606 coupled to exhaust source 632. In some embodiments, two or more (e.g., all) of the steps of method 200, and/or timing sequence 300 can be conducted without exposing the substrate to air or other oxygen-containing atmosphere.

Semiconductor processing system 600 can include one or more controller(s) 628 programmed or otherwise configured to cause one or more method steps as described herein to be conducted. Controller(s) 628 are coupled with the various power sources, heating systems, pumps, robotics and gas flow controllers, or valves of the reactor, as will be appreciated by the skilled artisan. By way of example, controller 628 can be configured to control gas flow of an etching gas, a diluting gas, and an inert gas into at least one of the one or more process chambers to etching a material on a substrate. The controller can be similarly configured to perform additional steps as described herein.

In some embodiments, the semiconductor processing system 600 is used to perform the method 200. In some embodiments, the semiconductor processing system 600 is used to perform the timing sequence 300. In some embodiments, the semiconductor processing system 600 is used to form the semiconductor structure 500.

The methods and systems disclosed herein can provide several benefits, including forming positive slope profile recesses and a substrate with uniformity, which are helpful for the following process (such as DED process).

Although embodiments of the present disclosure and their advantages have been described in detail, it should be understood that various changes, substitutions and alterations may be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. In addition, the scope of the present disclosure is defined by the scope of the appended claims. In addition, each scope of the claims is constructed as a separate embodiment, and various combinations of the claims and combinations of embodiments are within the scope of the present disclosure.

What is claimed is:

1. A method of forming a semiconductor structure, comprising:
in a process chamber, depositing a material on a sidewall of a recess;
providing an etching gas into the process chamber;
providing a diluting gas into the process chamber; and
providing a plasma into the process chamber.

2. The method as claimed in claim 1, wherein the etching gas comprises fluorine.

3. The method as claimed in claim 2, wherein the etching gas comprises at least one of the following: NF₃, SF₆, F₂, ClF₃, and CF₄.

4. The method as claimed in claim 2, wherein the etching gas is NF₃.

5. The method as claimed in claim 1, wherein the diluting gas comprises nitrogen.

6. The method as claimed in claim 5, wherein the diluting gas comprises at least one of the following: N₂, NH₃, N₂H₄, and N₂O.

7. The method as claimed in claim 5, wherein the diluting gas is N₂.

8. The method as claimed in claim 1, wherein the flow of the etching gas and the flow of the diluting gas are at least overlapped.

9. The method as claimed in claim 1, wherein the flow of the etching gas, the flow of the diluting gas, and the plasma are at least overlapped.

10. The method as claimed in claim 1, wherein the duration of the step of providing the etching gas into the process chamber is longer than the duration of the step of providing the plasma into the process chamber.

11. The method as claimed in claim 1, wherein the duration of the step of providing the diluting gas into the process chamber is longer than the duration of the step of providing the plasma into the process chamber.

12. The method as claimed in claim 1, wherein the flow rate of the diluting gas is greater than or equal to 5,000 SCCM.

13. The method as claimed in claim 1, wherein the flow rate of the diluting gas is greater than or equal to 7,000 SCCM.

14. The method as claimed in claim 1, further comprising repeating the step of depositing the material, the step of providing the etching gas, the step of providing the diluting gas, and the step of providing the plasma.

15. The method as claimed in claim 1, wherein the recess has an aspect ratio that is greater than or equal to 5:1.

16. The method as claimed in claim 1, further comprising providing an inert gas into the process chamber.

17. The method as claimed in claim 1, wherein the recess is formed on a substrate.

18. A semiconductor structure formed on a substrate using the method as claimed in claim 1.

19. The semiconductor structure as claimed in 18, wherein the side conformality of the remaining material is uniform across the substrate.

20. A semiconductor processing system, comprising:
a process chamber;
a susceptor, disposed in the process chamber and supporting a substrate;
an etching gas source, configured and arranged to provide an etching gas into the process chamber;
a diluting gas source, configured and arranged to provide a diluting gas into the process chamber;
a plasma source, configured and arranged to provide a plasma into the process chamber; and
a controller, configured to control the flow of the diluting gas into the process chamber, so as to perform the method as claimed in claim 1.
